(19) United States
(12) Patent Application Publication
(10) Pub. No.: US 2017/0084581 A1
(43) Pub. Date: Mar. 23, 2017

(54) LAMINATED CHIP, LAMINATED-CHIP-MOUNTED SUBSTRATE AND MANUFACTURING METHOD OF LAMINATED CHIP

(71) Applicant: FUJITSU LIMITED, Kawasaki-shi (JP)

(72) Inventors: Shunichi Kikuchi, Yokohama (JP); Hiroshi Onuki, Yokohama (JP); Naoaki Nakamura, Kawasaki (JP); Yoshihisa IWAKIRI, Kawasaki (JP)

(73) Assignee: FUJITSU LIMITED, Kawasaki-shi (JP)

(21) Appl. No.: 15/252,454

(22) Filed: Aug. 31, 2016

(30) Foreign Application Priority Data
Sep. 17, 2015 (JP) 2015-183944

(51) Int. Cl. H01L 25/065; H01L 23/00; H01L 25/00; H01L 23/544

(52) U.S. Cl. CPC H01L 25/0657; H01L 23/544; H01L 24/83; H01L 24/33; H01L 25/50; H01L 2223/54426; H01L 2225/06517; H01L 2225/06541

(57) ABSTRACT

A laminated chip includes: semiconductor chips that are laminated; and multiple types of adhesive insulating resin films that include mutually different characteristics and that are filled between the semiconductor chips, wherein the multiple types of the adhesive insulating resin films are arranged in a chip plane direction, depending on a demand characteristic for each region in a chip plane.

### CROSS-REFERENCE TO RELATED APPLICATIONS

This application is based upon and claims the benefit of prior Japanese Patent Application No. 2015-183944 filed on Sep. 17, 2015, the entire contents of which are incorporated herein by reference.

### FIELD

An embodiment relates to a laminated chip, a laminated-chip-mounted substrate and a manufacturing method of the laminated chip.

### BACKGROUND

As a technology for actualizing the functional advancement and downsizing of electronic equipment such as an HPC (High Performance Computing) and a server, there is known a three-dimensional packaging technology in which semiconductor chips such as LSIs (Large Scale Integration) are connected by silicon penetration electrodes (TSV: Through Si Via) and are laminated in a perpendicular direction. In relation to this, there is also known a technology in which an adhesive insulating resin film (NCF: Non Conductive Film) is filled between semiconductor chips that are laminated, for the purpose of the protection of interconnected chip terminals and the mechanical support of the semiconductor chips. For example, the adhesive insulating resin film is previously pasted on a terminal mounting surface of the semiconductor chip, and the terminals of the semiconductor chips are interconnected while the resin is cured by the thermal compression with a thermal compression bonder. Thereby, the semiconductor chips can be laminated.

By the way, a spherical filler is often added in the resin forming the adhesive insulating resin film. By changing the physical property of the filler that is added in the resin, it is possible to change the characteristic (for example, heat conductivity, permittivity and the like) of the adhesive insulating resin film. For example, by employing a high-heat-conductivity filler having a high heat conductivity, the enhancement of the heat radiation performance between the semiconductor chips can be expected. Further, by employing a low-permittivity filler having a low permittivity, the enhancement of the transmission performance between the semiconductor chips can be expected.

[Patent document 1] Japanese Laid-open Patent Publication No. 2013-122957

### SUMMARY

According to an aspect of the embodiment, a laminated chip includes: semiconductor chips that are laminated; and multiple types of adhesive insulating resin films that include mutually different characteristics and that are filled between the semiconductor chips, wherein the multiple types of the adhesive insulating resin films are arranged in a chip plane direction, depending on a demand characteristic for each region in a chip plane.

According to an aspect of the embodiment, a laminated-chip-mounted substrate includes: a substrate; a laminated chip that includes semiconductor chips that are laminated, the laminated chip being mounted on the substrate; and multiple types of adhesive insulating resin films that include mutually different characteristics and that are filled between the semiconductor chips, wherein the multiple types of the adhesive insulting resin film are arranged in a chip plane direction, depending on a demand characteristic for each region in a chip plane.

According to an aspect of the embodiment, a manufacturing method of a laminated chip that is mounted on a substrate, the manufacturing method of the laminated chip includes: filling multiple types of adhesive insulating resin films that include mutually different characteristics between semiconductor chips; and laminating the semiconductor chips to each other, wherein, in the filling, the multiple types of the adhesive insulting resin films are arranged in a chip plane direction, depending on a demand characteristic for each region in a chip plane.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a cross-section structure of a semiconductor device according to an embodiment;

FIG. 2 is an enlarged view of a bonding part between semiconductor chips that are laminated according to the embodiment;

FIG. 3 is a diagram illustrating a demand characteristic map on a chip plane of the semiconductor chip according to the embodiment;

FIG. 4 is a diagram exemplifying a planar arrangement pattern of NCFs that are arranged between the semiconductor chips according to the embodiment;

FIG. 5A is a diagram (1) illustrating a manufacturing method of a laminated chip in the embodiment;

FIG. 5B is a diagram (2) illustrating the manufacturing method of the laminated chip in the embodiment;

FIG. 6A is a diagram illustrating a pattern of an NCF that is pasted on a terminal formation surface of a first semiconductor chip according to the embodiment;

FIG. 6B is a diagram illustrating a pattern of an NCF that is pasted on a terminal formation surface of a second semiconductor chip according to the embodiment;

FIG. 7 is a diagram illustrating a demand characteristic map on a chip plane of a semiconductor chip according to a first modification;

FIG. 8 is a diagram illustrating a planar arrangement pattern of NCFs that are filled between the semiconductor chips according to the first modification;

FIG. 9A is a diagram illustrating a pattern of an NCF that is pasted on a terminal formation surface of a first semiconductor chip according to the first modification;

FIG. 9B is a diagram illustrating a pattern of an NCF that is pasted on a terminal formation surface of a second semiconductor chip according to the first modification;

FIG. 10 is a diagram illustrating a pattern of an NCF that is pasted on a terminal formation surface of a second semiconductor chip according to a second modification;

FIG. 11 is a diagram illustrating a planar arrangement pattern of NCFs that are filled between semiconductor chips according to a third modification;

FIG. 12A is a diagram illustrating a pattern of an NCF that is pasted on a terminal formation surface of a first semiconductor chip in the third modification; and

FIG. 12B is a diagram illustrating a pattern of an NCF that is pasted on a terminal formation surface of a second semiconductor chip in the third modification.

### DESCRIPTION OF EMBODIMENT

In the plane of the semiconductor chip, there are often multiple regions that are different in demand characteristic (object), as exemplified by a high-heat-generating region that produces a high heat generation amount, and a high-frequency-signal region that raises a fear of the attenuation of high frequency signals. Meanwhile, in the case of arranging, between the semiconductor chips, an adhesive insulating resin film in which a high-heat-conductivity filler is added, there is an effect on the high-heat-generating region in the chip plane, but it is sometimes difficult to improve the attenuation of high frequency signals at the high-frequency-signal region. To the contrary, in the case of arranging, between the semiconductor chips, an adhesive insulating resin film in which a low-permittivity filler is added, there is an effect on the high-frequency-signal region, but it is sometimes difficult to sufficiently radiate the heat of the high-heat-generating region.

That is, conventionally, in the case where, in the chip plane, there are multiple regions that are different in demand characteristic (object), it is difficult to satisfy these simultaneously. Here, the development of a novel material for simultaneously adjusting multiple characteristics such as heat conductivity and permittivity is not very realistic because a great development cost and a great labor load are imposed.

Hereinafter, a laminated chip, a laminated-chip-mounted substrate and a manufacturing method of the laminated chip according to an embodiment will be described in detail, with reference to the drawings.

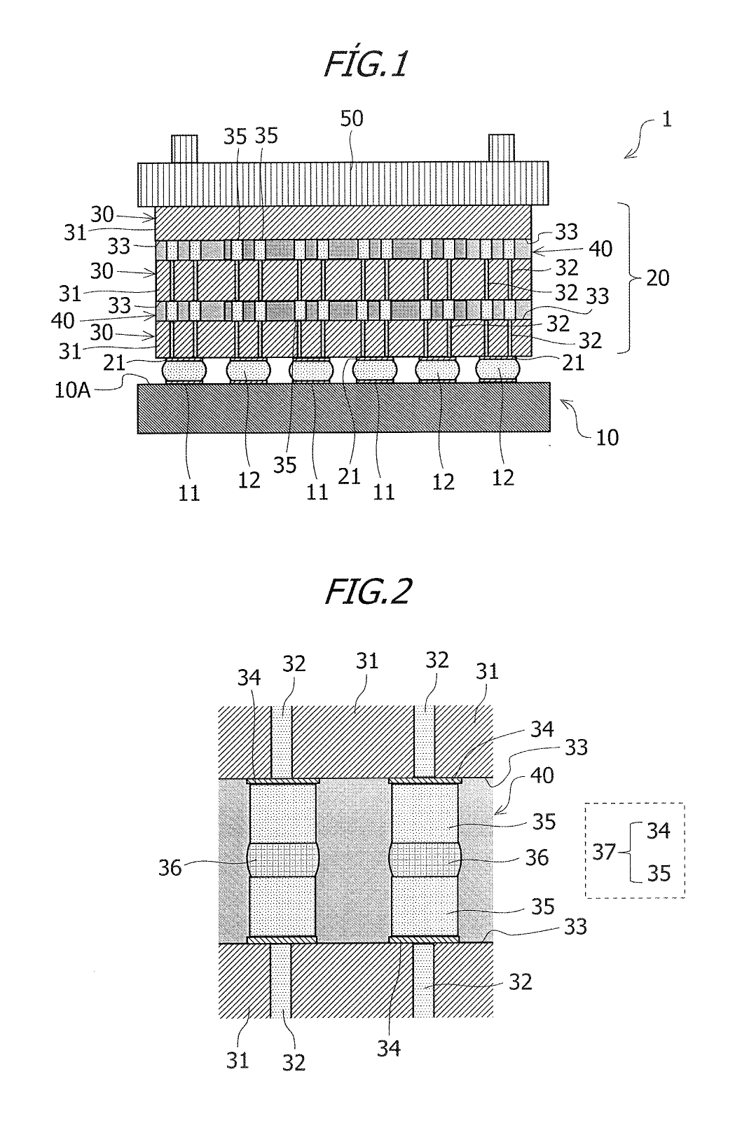

FIG. 1 is a diagram illustrating a cross-section structure of a semiconductor device 1 according to the embodiment. The semiconductor device 1 includes a substrate 10 and a laminated chip 20 that is mounted on the substrate 10. The laminated chip 20 includes multiple semiconductor chips 30 that are laminated to each other, and NCFs (Non Conductive Films) 40 that are adhesive insulating resin films are filled among the semiconductor chips 30.

The semiconductor chip 30, for example, is an LSI (Large Scale Integration), but may be another active element such as an IC (Integrated Circuit), or may be a passive element such as a resistor, a capacitor or a coil.

Reference character 10A denotes a mounting surface of the substrate 10. On the mounting surface 10A of the substrate 10, electrode pads 11 are formed. The electrode pads 11 are connected electrically and mechanically with electrode pads 21 formed on the under surface of the laminated chip 20, through solder bumps 12. The under surface of the laminated chip 20 is the under surface of a semiconductor chip 30 that is of multiple laminated chips 30 included in the laminated chip 20 and that is positioned at the undermost layer.

In the example illustrated in FIG. 1, the laminated chip 20 includes three semiconductor chips 30 that are laminated. The semiconductor chip 30, for example, is an LSI (Large Scale Integration), but may be another active element such as an IC (Integrated Circuit), or may be a passive element such as a resistor, a capacitor or a coil. Here, the number of laminations of semiconductor chips 30 of the laminated chip 20 can be appropriately changed. On the top surface of a semiconductor chip 30 that is of the semiconductor chips 30 included in the laminated chip 20 and that is positioned at the topmost layer, a cooling plate 50 is placed, and the laminated chip 20 can be cooled by the cooling plate 50.

The semiconductor chip 30 includes semiconductor substrates 31, and penetration electrodes 32 provided in the semiconductor substrates 31. The penetration electrode 32 is a so-called silicon penetration electrode (TSV: Through Si Via) that penetrates the semiconductor substrate 31. Reference numeral 33 denotes a “terminal formation surface” formed on the principal surface of the semiconductor substrate 31 of the semiconductor chip 30.

FIG. 2 is an enlarged view of a bonding part between semiconductor chips 30 that are laminated. On the terminal formation surfaces 33 of the semiconductor substrates 31, electrode pads 34 are formed. The penetration electrode 32 penetrating the semiconductor chip 30 is a perpendicular wire that electrically connects the electrode pads 34 formed on the terminal formation surfaces 33 at the top surface side and under surface side of the semiconductor substrate 31. Here, the electrode pads on the terminal formation surfaces 33 are connected with pillar electrodes, for example, CPBs (Cupper Pillar Bumps: hereinafter, referred to as Cu pillars) 35, and the Cu pillars 35 of the semiconductor chips 30 that are vertically laminated are bonded to each other by solder bonding parts 36. Here, in FIG. 1, the illustration of the electrode pads 34 formed on the terminal formation surfaces 33 is omitted.

Next, the NCF 40 will be described. The NCF 40 is a film-shaped insulating adhesive member that is filled between the semiconductor chips 30 for the purpose of the mechanical support of the semiconductor chips 30 that are laminated and the protection of connection terminals 37 (see FIG. 2) including the electrode pads 34 and Cu pillars 35 of the semiconductor chips 30. The NCF 40 has, for example, an insulating resin such as a thermosetting epoxy resin, and a spherical filler is contained in the insulating resin. The NCF 40 is in a solid state, for example, at ordinary temperature (about 25° C.), and is in a liquid state until the temperature rises from the ordinary temperature and reaches a reaction start temperature (about 120° C. to about 130° C.), because of the decrease in viscosity. When the temperature further rises and reaches the reaction start temperature, the viscosity increases and the NCF 40 becomes a semi-solid state.

Further, in the NCF 40, by changing the physical property of the filler that is added in the insulating resin, it is possible to change the characteristic (for example, heat conductivity, permittivity and the like) of the NCF 40. For example, by employing a high-heat-conductivity filler having a high heat conductivity in the insulating resin of the NCF 40, it is possible to achieve the enhancement of the heat radiation performance between the semiconductor chips 30. Further, by employing a low-permittivity filler having a low permittivity in the insulating resin of the NCF 40, it is possible to achieve the enhancement of the transmission performance between the semiconductor chips 30.

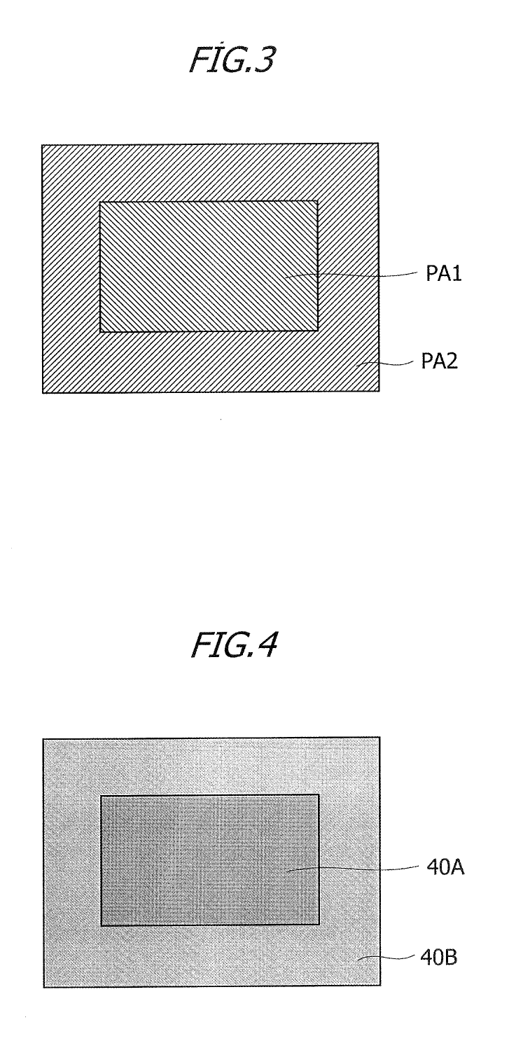

FIG. 3 is a diagram illustrating a demand characteristic map on a chip plane of the semiconductor chip 30. In other words, FIG. 3 is a diagram in which the chip plane of the semiconductor chip 30 is divided into regions depending on the demand characteristic of the NCF 40. Reference character PA1 illustrated in FIG. 3 denotes a “high-heat-generating region” at which the heat generation amount is greater compared to the other region and the NCF 40 is demanded to have a high heat conductivity. Reference character PA2 denotes a “high-frequency-signal region” at which high speed signals are transmitted through the connection terminal 37 and the NCF 40 is demanded to have a high transmission speed characteristic. As illustrated in FIG. 3, on the chip plane of the semiconductor chip 30, there are multiple regions that are different in the demand characteristic (object) of the NCF 40.

Meanwhile, in the case of arranging, between the semiconductor chips 30, an NCF in which a high-heat-conductivity filler is added, there is an effect on the high-heat-generating region PA1, but there is a likelihood that it is difficult to sufficiently satisfy the transmission speed of high frequency signals at the high-frequency-signal region PA2. To the contrary, in the case of arranging, between the semiconductor chips 30, an NCF in which a low-permittivity filler is added, there is an effect on the high-frequency-signal region PA2, but there is a likelihood that it is difficult to sufficiently radiate the heat of the high-heat-generating region PA1.

Hence, as illustrated in FIG. 4, in the embodiment, in order to satisfy the demand characteristic for each region in the chip plane of the semiconductor chip 30, multiple types of NCFs 40 having different characteristics for each planar region are arranged along the chip plane direction. FIG. 4 is a diagram exemplifying a planar arrangement pattern of the NCFs 40 that are arranged between the semiconductor chips 30 according to the embodiment. In FIG. 4, reference character 40A denotes an NCF in which a high-heat-conductivity filler is added in the insulating resin (hereinafter, referred to as a “high-heat-conductivity NCF”). Reference character 40B denotes an NCF in which a low-permittivity filler is added in the insulating resin (hereinafter, referred to as a “low-permittivity NCF”). Here, the high-heat-conductivity NCF 40A and the low-permittivity NCF 40B are referred to as the NCF 40, when being collectively called.

In the example illustrated in FIG. 3 and FIG. 4, the high-heat-conductivity NCF 40A is arranged at a position corresponding to the high-heat-generating region PA1 at the central part side on the chip plane. Further, the low-permittivity NCF 40B is arranged at a position corresponding to the high-frequency-signal region PA2 of the semiconductor chip 30, so as to surround the outer circumference of the high-heat-conductivity NCF 40A. When the high-heat-conductivity NCF 40A is arranged at the position corresponding to the high-heat-generating region PA1 of the semiconductor chip 30 in this way, it is possible to promote the heat radiation of the high-heat-generating region PA1 and to sufficiently cool the high-heat-generating region PA1. Then, when the low-permittivity NCF 40B is arranged at the position corresponding to the high-frequency-signal region PA2 of the semiconductor chip 30, it is possible to increase the transmission speed of high frequency signals at the high-frequency-signal region PA2. Here, the demand characteristics for the regions in the chip plane and the combination of the NCFs 40 having the characteristics corresponding to the demand characteristics, which are illustrated in FIG. 3 and FIG. 4, are examples, and can be appropriately changed.

Thus, in the laminated chip 20 according to the embodiment, the NCFs 40 having different characteristics are arranged in the chip plane direction, depending on the demand characteristic for each region in the laminated chip plane. Therefore, even in the case where, in the chip plane, there are multiple regions that are different in demand characteristic (object), it is possible to satisfy these demands simultaneously. For example, although a general NCF has a heat conductivity of 0.3 (W/m·K), a relative permittivity of 3.5 and a dielectric tangent of about 0.009, the high-heat-conductivity NCF 40A can have a heat conductivity of about 1.0 (W/m·K) and can have more than three times the heat radiation performance. Further, when the low-permittivity NCF 40B has a relative permittivity of about 2.4 and a dielectric tangent of about 0.003, it is possible to enhance the transmission speed of signals by about 20% and reduce the loss to about ⅓, compared to a general NCF. Furthermore, in the embodiment, even in the case where, in the chip plane, there are multiple regions that are different in demand characteristic, it is possible to satisfy the demand characteristic for each region in a simple structure, without a great development cost and labor load due to the development of a novel material for the NCF or the like.

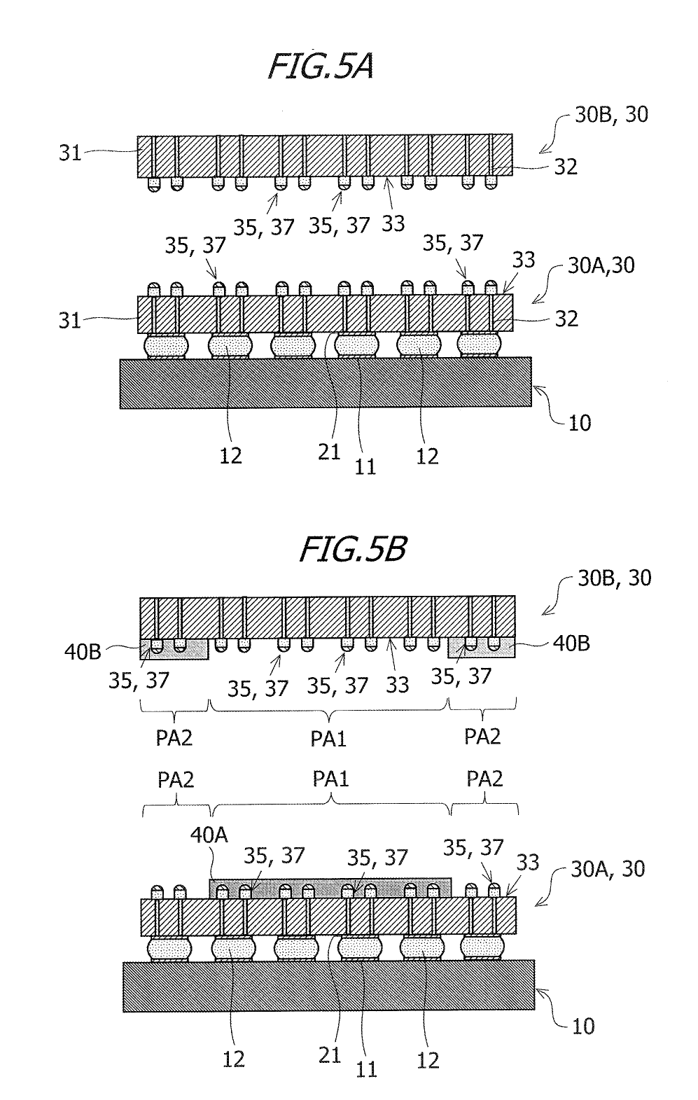

Next, a manufacturing method of the laminated chip 20 in the embodiment will be described. First, as illustrated in FIG. 5A, the semiconductor chips 30 that are laminated to each other are prepared. As described above, the multiple connection terminals 37 including the electrode pads 34 and the Cu pillars 35 are formed on the terminal formation surfaces 33 of the semiconductor chips 30. Further, semispherical solder bumps are formed at the tip sides of the Cu pillars 35.

Next, as illustrated in FIG. 5B, the high-heat-conductivity NCF 40A and the low-permittivity NCF 40B are pasted on the terminal formation surfaces 33 of the semiconductor chips 30, so as to cover connection terminals 37 including Cu pillars 35. Specifically, as described in FIGS. 3 and 4, in accordance with the demand characteristic map for the semiconductor chips 30, the high-heat-conductivity NCF 40A is pasted at the region corresponding to the high-heat-generating region PA1, and the low-permittivity NCF 40B is pasted at the region corresponding to the high-frequency-signal region PA2. On that occasion, in the embodiment, one of the high-heat-conductivity NCF 40A and low-permittivity NCF 40B that are arranged so as to be adjacent to each other in the single chip plane is pasted on one of the two semiconductor chips 30 that are laminated. Further, the other of the high-heat-conductivity NCF 40A and low-permittivity NCF 40B that are arranged so as to be adjacent to each other in the single chip plane is pasted on the other of the two semiconductor chips 30 that are laminated.

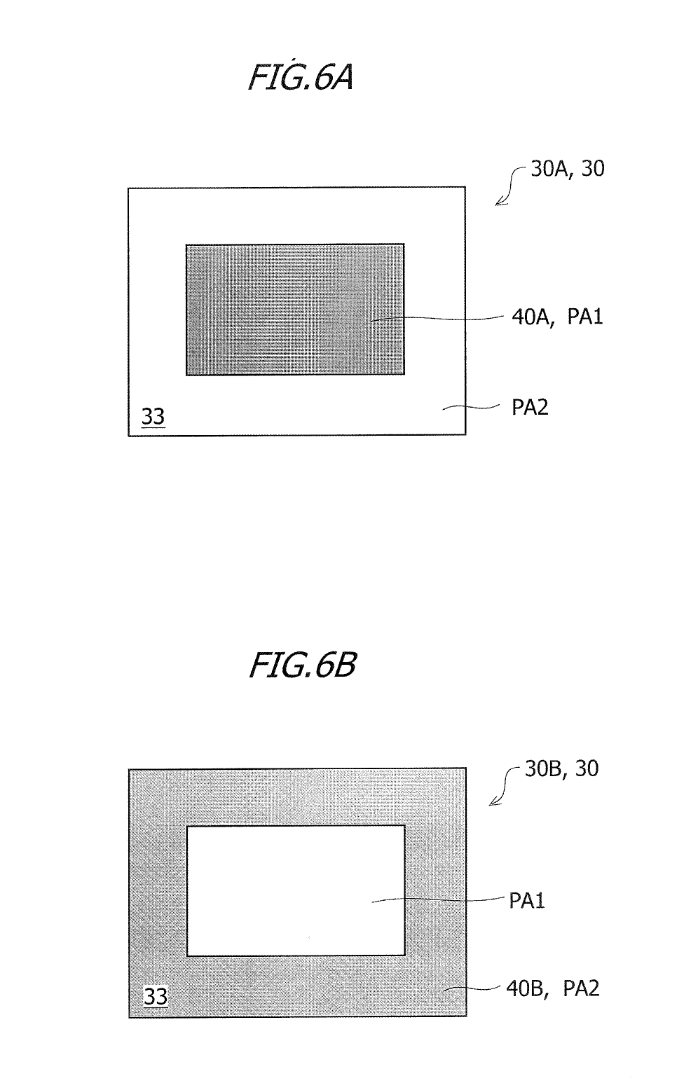

Here, one of a pair of semiconductor chips 30 that laminated to each other illustrated in FIGS. 5A and 5B is referred to as a first semiconductor chip 30A, and the other is referred to as a second semiconductor chip 30B. FIG. 6A is a diagram illustrating a pattern of the NCF that is pasted on the terminal formation surface 33 of the first semiconductor chip 30A according to the embodiment. FIG. 6B is a diagram illustrating a pattern of the NCF that is pasted on the terminal formation surface 33 of the second semiconductor chip 30B according to the embodiment. As illustrated in FIG. 6A, on the terminal formation surface 33 of the first semiconductor chip 30A, the high-heat-conductivity NCF 40A is pasted at the high-heat-generating region PA1 that is positioned at the central part side on the chip plane. Here, on the terminal formation surface 33 of the first semiconductor chip 30A, the high-frequency-signal region PA2 that is positioned at the outer circumference side of the high-heat-generating region PA1 is an NCF absence region where the NCF is not pasted (illustrated as a white color region in FIG. 6A). The high-heat-conductivity NCF 40A may be arranged solely at the high-heat-generating region PA1, for example, by pasting the high-heat-conductivity NCF 40A on the whole of the terminal formation surface 33 of the first semiconductor chip 30A and thereafter cutting away the high-heat-conductivity NCF 40A at the NCF absence region with a laser or the like. Here, the high-heat-conductivity NCF 40A that has been cut into a predetermined shape in advance may be pasted at the high-heat-generating region PA1 on the terminal formation surface 33 of the first semiconductor chip 30A.

On the other hand, as illustrated in FIG. 6B, on the terminal formation surface 33 of the second semiconductor chip 30B, the low-permittivity NCF 40B is pasted at the high-heat-frequency-signal region PA2 that is positioned at the outer circumference side on the chip plane. Here, on the terminal formation surface 33 of the second semiconductor chip 30B, the high-heat-generating region PA1 that is positioned at the inner circumference side of the high-frequency-signal region PA2 is an NCF absence region where the NCF is not pasted (illustrated as a white color region in FIG. 6B). The low-permittivity NCF 40B may be arranged solely at the high-frequency-signal region PA2, for example, by pasting the low-permittivity NCF 40B on the whole of the terminal formation surface 33 of the second semiconductor chip 30B and thereafter cutting away the low-permittivity NCF 40B at the NCF absence region with a laser or the like. Here, the low-permittivity NCF 40B that has been cut into a predetermined shape in advance may be pasted at the high-frequency-signal region PA2 on the terminal formation surface 33 of the second semiconductor chip 30B. Further, the pasting of the NCF 40 on the terminal formation surface 33 can be performed using a publicly known vacuum laminator (for example, Part Number: CV-300, manufactured by Nichigo-Morton Co., Ltd.). Here, in FIG. 6A and FIG. 6B, the illustration of the connection terminals 37 on the terminal formation surfaces 33 is omitted.

Next, in the manufacturing of the laminated chip 20, the terminal formation surfaces 33 of the first semiconductor chip 30A and the second semiconductor chip 30B are made face each other, and the first semiconductor chip 30A and the second semiconductor chip 30B are made close to each other in a state in which the positions of the Cu pillars 35 are mutually matched. On that occasion, the Cu pillars 35 of the second semiconductor chip 30B come close to the Cu pillars 35 of the first semiconductor chip 30A, while crushing the high-heat-conductivity NCF 40A pasted on the terminal formation surface 33 of the first semiconductor chip 30A. Further, the Cu pillars 35 of the first semiconductor chip 30A come close to the Cu pillars 35 of the second semiconductor chip 30B, while crushing the low-permittivity NCF 40B pasted on the terminal formation surface 33 of the second semiconductor chip 30B. Then, in a state in which the solder bumps formed at the tip sides of the Cu pillars 35 of the first semiconductor chip 30A and the second semiconductor chip 30B contact with each other, the thermal compression is performed, for example, using a vacuum reflow apparatus. Thereby, the insulating resins of the high-heat-conductivity NCF 40A and the low-permittivity NCF 40B thermally cure. Then, the solder bumps of the Cu pillars 35 of the first semiconductor chip 30A and second semiconductor chip 30B confronted with each other melt by thermal compression, and are integrally bonded, so that the solder bonding parts 36 are formed (see FIG. 2).

Thereby, the lamination of the first semiconductor chip 30A and the second semiconductor chip 30B is completed. Then, depending on the number of laminations of the semiconductor chips 30 included in the laminated chip 20, the semiconductor chips 30 are sequentially laminated, so that the laminated chip 20 is obtained. Here, in the manufacturing of the laminated chip 20, the semiconductor chips 30 may be laminated in a lump.

Here, examples of the above-described high-heat-conductivity filler contained in the insulating resin of the high-heat-conductivity NCF 40A include magnesium oxide (MgO), alumina (Al₂O₃), hexagonal boron nitride (BN), aluminum nitride (AlN), silicon carbide (SiC), diamond (C) and silica (SiO₂). The heat conductivity of the high-heat-conductivity NCF 40A tends to increase as the content rate of the above filler in the high-heat-conductivity NCF 40A increases, but the characteristic of the high-heat-conductivity NCF 40A is influenced also by the particle diameter, particle shape and others of the filler. As the high-heat-conductivity NCF 40A, for example, TSA-31 (heat conductivity, 1 W/m·K), TSA-32 (heat conductivity, 2 W/m·K), TSA-33 (heat conductivity, 3 W/m·K) or the like, which is commercially available from TORAY INDUSTRIES, INC., may be used.

Further, examples of the above-described low-permittivity filler contained in the insulating resin of the low-permittivity NCF 40B include hexagonal boron nitride (BN), magnesium oxide (MgO), silica (SiO₂) and alumina (Al₂O₃). As the low-permittivity NCF 40B, for example, NC0204 or the like, which is commercially available from NAMICS CORPORATION, may be used. Here, in the embodiment, the low-permittivity NCF 40B is arranged at the region corresponding to the high-frequency-signal region PA2 of the semiconductor chip 30, but instead, an NCF 40 that contains a low-dielectric-tangent filler having a low dielectric tangent may be arranged. A lower dielectric tangent makes it possible to reduce the transmission loss of high frequency signals to a greater degree, and is more advantageous against the attenuation of high frequency signals.

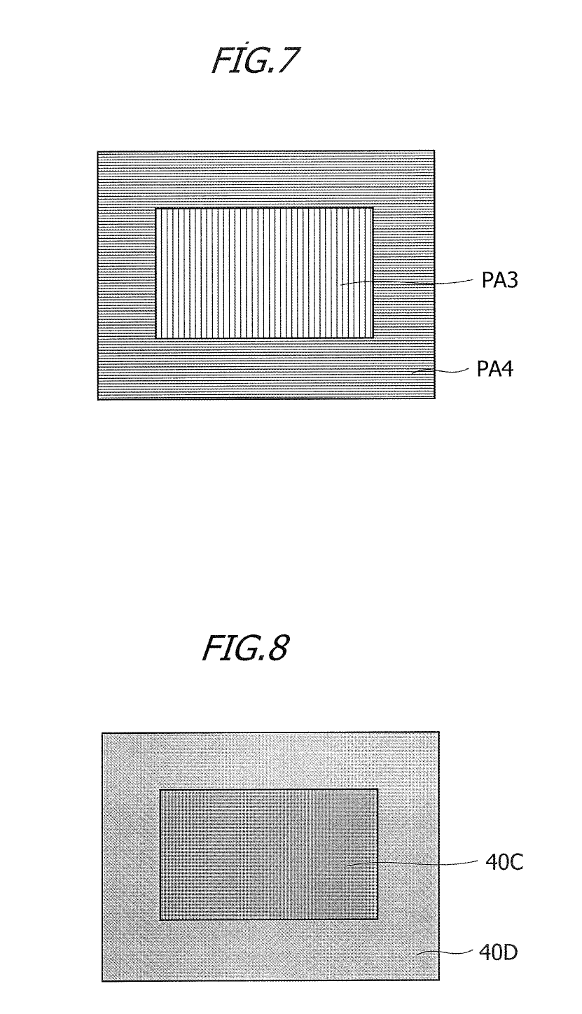

Hereinafter, modifications of the above-described embodiment will be described. FIG. 7 is a diagram illustrating a demand characteristic map on the chip plane of the semiconductor chip 30 according to a first modification. The region denoted by reference character PA3 that is positioned at the central part on the chip plane is a “low-Young's-modulus region” where the NCF 40 is demanded to have a low Young's modulus. Further, the region denoted by reference character PA4 that is positioned at the outer circumference part on the chip plane is a “low-thermal-expansibility region” where the NCF 40 is demanded to have a low thermal expansibility.

FIG. 8 is a diagram illustrating a planar arrangement pattern of NCFs 40 that are filled between the semiconductor chips 30 according to the first modification. In FIG. 8, reference character 40C denotes an NCF in which a low-Young's-modulus filler is added in the insulating resin (hereinafter, referred to as a “low-Young's-modulus NCF”). Reference character 40D denotes an NCF in which a low-thermal-expansibility filler is added in the insulating resin (hereinafter, referred to as a “low-thermal-expansibility NCF”). Examples of the low-Young's-modulus filler contained in the insulating resin of the low-Young's-modulus NCF 40C include hexagonal boron nitride (BN), magnesium hydroxide (Mg(OH)₂), magnesium oxide (MgO) and alumina (Al₂O₃). For the low-Young's-modulus NCF 40C, it is possible to decrease the Young's modulus of the NCF, by selecting a low-hardness filler or by reducing the filler content rate. Further, examples of the low-thermal-expansibility filler contained in the insulating resin of the low-thermal-expansibility NCF 40D include silica (SiO₂), alumina (Al₂O₃) and aluminum nitride (AlN).

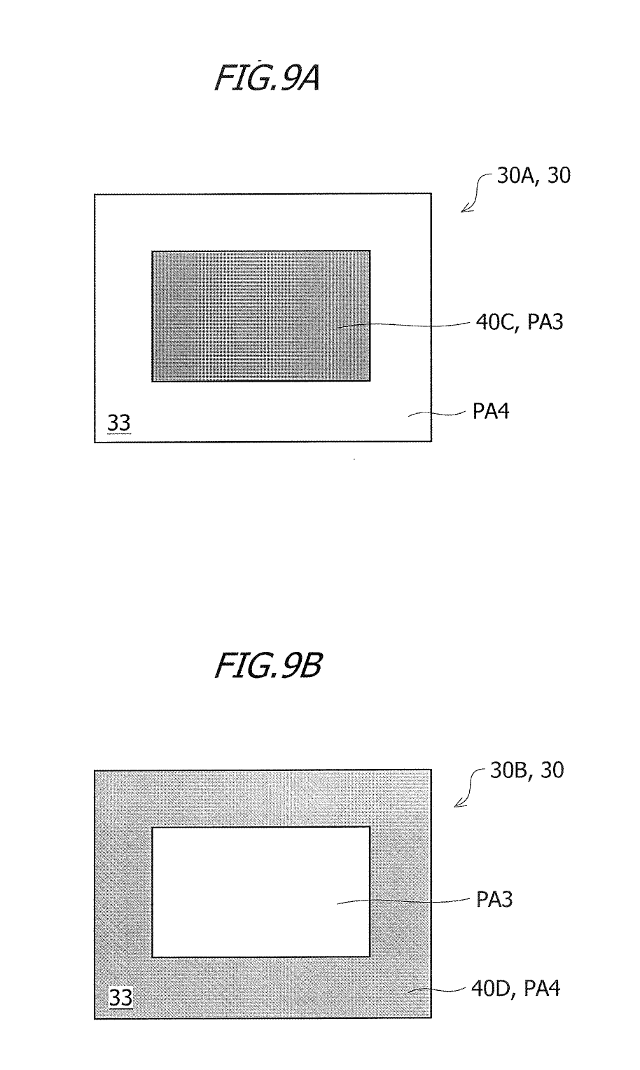

FIG. 9A is a diagram illustrating a pattern of an NCF that is pasted on the terminal formation surface 33 of the first semiconductor chip 30A according to the first modification. FIG. 9B is a diagram illustrating a pattern of an NCF that is pasted on the terminal formation surface 33 of the second semiconductor chip 30B according to the first modification. As illustrated in FIG. 9A, on the terminal formation surface 33 of the first semiconductor chip 30A, the low-Young's-modulus NCF 40C is pasted at a region corresponding to the low-Young's-modulus region PA3 that is positioned at the central side on the chip plane. Here, on the terminal formation surface 33 of the first semiconductor chip 30A, the low-thermal-expansibility region PA4 that is positioned at the outer circumference side of the low-Young's-modulus region PA3 is an NCF absence region where the NCF is not pasted (illustrated as a white color region in FIG. 9A). On the other hand, as illustrated in FIG. 9B, on the terminal formation surface 33 of the second semiconductor chip 30B, the low-thermal-expansibility NCF 40D is pasted at the low-thermal-expansibility region PA4 that is positioned at the outer circumference side on the chip plane. Further, on the terminal formation surface 33 of the second semiconductor chip 30B, the low-Young's-modulus region PA3 that is positioned at the inner circumference side of the low-thermal-expansibility region PA4 is an NCF absence region where the NCF is not pasted (illustrated as a white color region in FIG. 9B). By laminating the first semiconductor chip 30A and the second semiconductor chip 30B illustrated in FIG. 9A and FIG. 9B, it is possible to obtain the laminated chip 20 in which the low-Young's-modulus NCF 40C and the low-thermal-expansibility NCF 40D, which have different characteristics, are arrayed in the chip plane direction. Here, in FIG. 9A and FIG. 9B, the illustration of the connection terminals 37 on the terminal formation surfaces 33 is omitted.

Here, in the laminated chip 20 according to the first modification, since the low-Young's-modulus NCF 40C is arranged on the low-Young's-modulus region PA3 that is positioned at the central side on the chip plane, it is possible to crush the insulating resin of the low-Young's-modulus NCF 40C by a smaller force, at the time of the chip lamination. Thereby, at the time of the chip lamination, the insulating resin of the low-Young's-modulus NCF 40C easily flows from the central side to the outer circumference side on the chip plane. Thereby, at the time of the manufacturing of the laminated chip 20, it is possible to easily crush the insulating resin of the low-Young's-modulus NCF 40C and to enhance the manufacturability of the laminated chip 20. Here, in the low-Young's-modulus NCF 40C, a low-viscosity type resin may be used as the insulating resin. Thereby, there is an advantage in that the insulating resin of the NCF flows much more easily from the central side to the outer circumference side on the chip plane, at the time of the chip lamination.

Meanwhile, at the outer circumference region on the chip plane, the thermal expansion easily occurs by the repeat of on/off of the LSI after the manufacturing of the semiconductor device 1. Then, when a warp appears at the outer circumference region on the chip plane due to the thermal expansion, there is a fear that the solder bonding part 36 is damaged or is broken away. In response, the low-thermal-expansibility NCF 40D is arranged at the low-thermal-expansibility region PA4 that is positioned at the outer circumference side on the chip plane, and thereby, it is possible to suppress the warp of the low-thermal-expansibility region PA4 and to inhibit the damage and others of the solder bonding part 36. Here, in the first modification, the low-Young's-modulus NCF 40C may be pasted at the low-Young's-modulus region PA3 that is positioned at the central side of the second semiconductor chip 30B, and the low-thermal-expansibility NCF 40D may be pasted at the low-thermal-expansibility region PA4 that is positioned at the outer circumference side of the first semiconductor chip 30A.

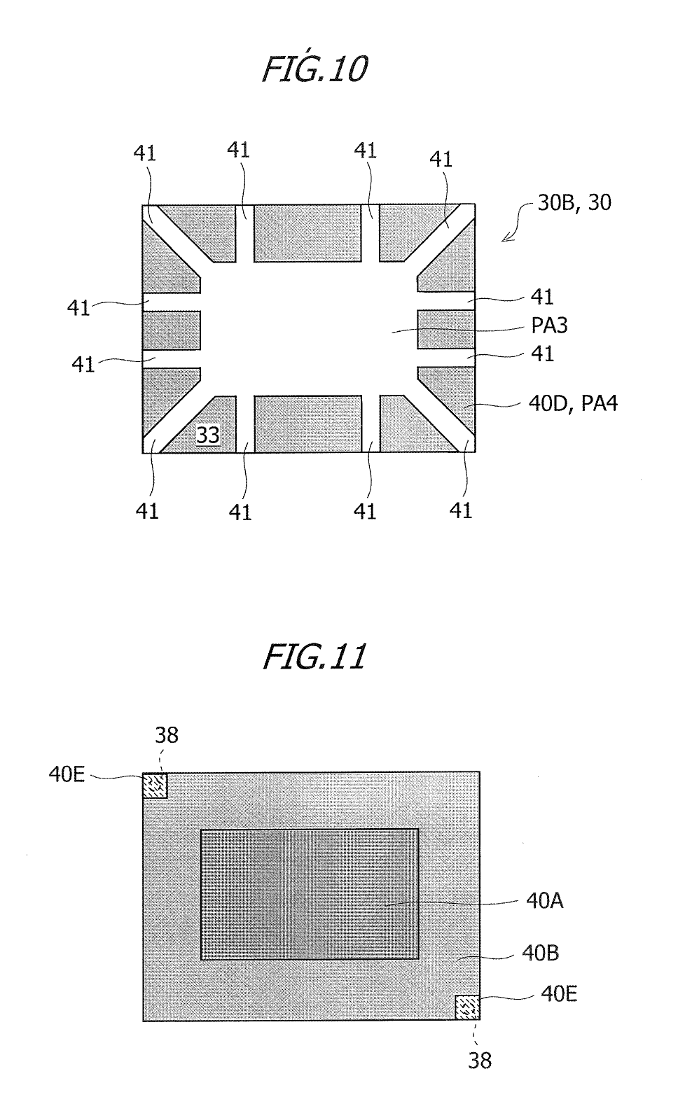

FIG. 10 is a diagram illustrating a pattern of an NCF that is pasted on the terminal formation surface 33 of the second semiconductor chip 30B in a second modification. Here, the pattern of an NCF that is pasted on the terminal formation surface 33 of the first semiconductor chip 30A in the second modification is the same as that in the first modification illustrated in FIG. 9A. In the example illustrated in FIG. 10, multiple cutout parts 41 are provided in the NCF (the low-thermal-expansibility NCF 40D in the example illustrated in FIG. 10) that is pasted at the outer circumference region on the chip plane of the second semiconductor chip 30B. The cutout part 41 is a hollow part by which the insulating resin of the NCF (the low-Young's-modulus NCF 40C in the example illustrated in FIG. 9A) that is pasted at the chip inner circumference side of the first semiconductor chip 30A flows and goes away to the outer circumference side at the time of the chip lamination. Since the cutout parts 41 are formed in the NCF that is arranged at the outer circumference region on the chip plane, the NCF (the low-Young's-modulus NCF 40C in the example illustrated in FIG. 9A) that is arranged at the chip inner circumference side easily goes away to the outer circumference side at the time of the chip lamination, and it is possible to increase the manufacturability. Particularly, in the second modification, the cutout parts 41 are arranged so as to contact with the low-Young's-modulus NCF 40C that is positioned at the inner circumference side on the chip plane, and therewith, the cutout parts 41 are arranged in a radial manner. Thereby, at the time of the lamination of the first semiconductor chip 30A and the second semiconductor chip 30B, the insulating resin of the low-Young's-modulus NCF 40C goes away much more easily to the outer circumference region through the cutout parts 41.

Here, FIG. 11 is a diagram illustrating a planar arrangement pattern of the NCF 40 that is filled between the semiconductor chips 30 according to a third modification. In the third modification, at a pair of corner parts (nook parts) that are diagonally positioned on the chip plane, NCFs 40E that are lower in filler content compared to the other region (hereinafter, referred to as “filler-reduction NCFs”) are arranged.

On the terminal formation surface 33 of the first semiconductor chip 30A according to the third modification, alignment marks 38 to be read by an imaging apparatus are formed, for performing the alignment between the first semiconductor chip 30A and the second semiconductor chip 30B at the time of the chip lamination. The alignment marks 38 are formed at a pair of corner parts (nook parts) that are diagonally positioned on the terminal formation surface 33 of the first semiconductor chip 30A. In the third modification, the filler-reduction NCFs 40E are arranged at regions PA5 where the alignment marks 38 are formed (hereinafter, referred to as “alignment mark formation regions”). The others are the same as the arrangement pattern illustrated in FIG. 3. Here, in FIG. 11, the alignment marks 38 having a round shape are illustrated, but the shape of the alignment mark 38 is not particularly limited, and may be, for example, a cross shape or another shape. Further, the alignment marks 38 may be formed on the terminal formation surface 33 of the second semiconductor chip 30B, and the arrangement positions and number of alignment marks 38 are not particularly limited.

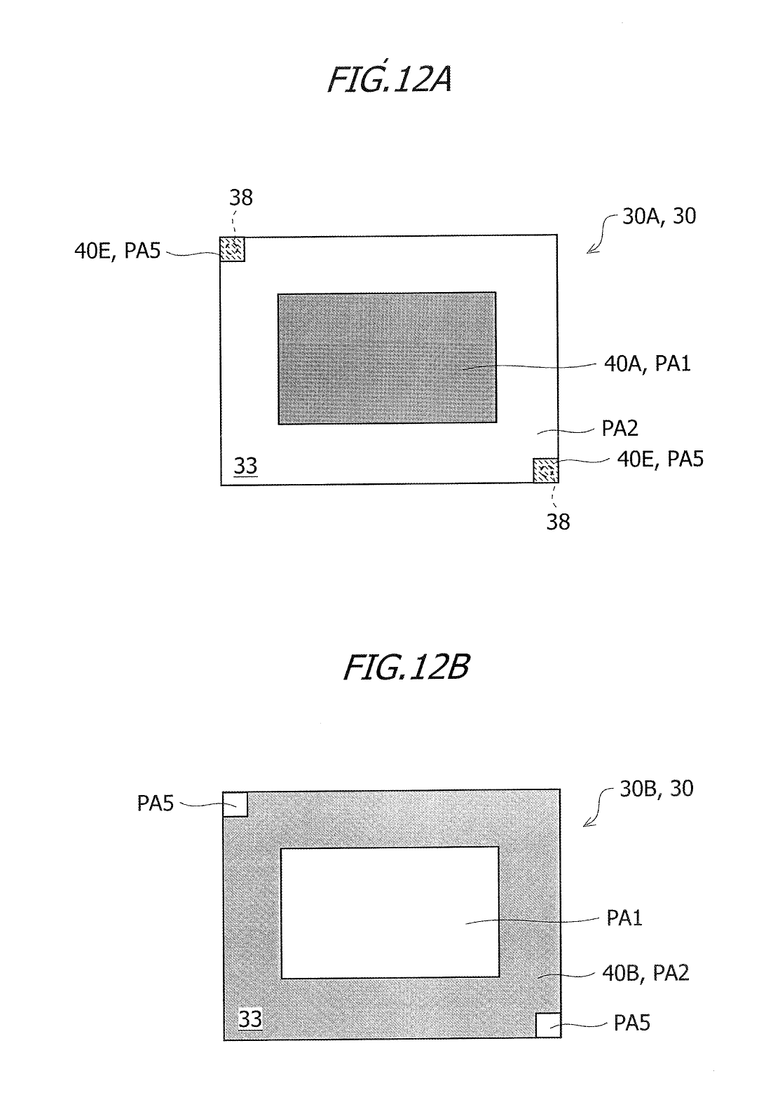

FIG. 12A is a diagram illustrating a pattern of an NCF that is pasted on the terminal formation surface 33 of the first semiconductor chip 30A in the third modification. FIG. 12B is a diagram illustrating a pattern of an NCF that is pasted on the terminal formation surface 33 of the second semiconductor chip 30B in the third modification. As illustrated in FIG. 12A, on the terminal formation surface 33 of the first semiconductor chip 30A, the high-heat-conductivity NCF 40A is pasted at the high-heat-generating region PA1 that is positioned at the central side on the chip plane. Furthermore, on the terminal formation surface 33 of the first semiconductor chip 30A, the filler-reduction NCFs 40E are pasted at the alignment mark formation regions PA5 that are positioned at the corner parts on the chip plane. Further, on the terminal formation surface 33 of the first semiconductor chip 30A, the high-frequency-signal region PA2 is an NCF absence region (illustrated as a white color region in FIG. 12A).

On the other hand, on the terminal formation surface 33 of the second semiconductor chip 30B, the low-permittivity NCF 40B is pasted at the high-frequency-signal region PA2 that is positioned at the outer circumference side of the high-heat-generating region PA1 on the chip plane. Further, on the terminal formation surface 33 of the second semiconductor chip 30B, the high-heat-generating region PA1 that is positioned at the inner side of the high-frequency-signal region PA2 and the alignment mark formation regions PA5 at the corners are NCF absence regions (illustrated as white color regions in FIG. 12B). In the filler-reduction NCFs 40E, the content rates are lower compared to the NCFs that are pasted at the other regions on the chip plane (the high-heat-conductivity NCF 40A and the low-permittivity NCF 40B in the third modification).

Here, as the content of the filler contained in the insulating resin of the NCF increases, the color of the NCF becomes darker and the recognition accuracy of the imaging apparatus for the alignment mark decreases more easily. In response, according to the third modification, the filler-reduction NCF 40E is arranged at the alignment mark formation region PA5 on the chip plane, so that the filler-reduction NCF 40E covers the alignment mark 38. As a result, it is possible to inhibit the deterioration in the recognition accuracy of the imaging apparatus for the alignment mark 38. Here, in the filler-reduction NCF 40E in the third modification, the filler does not need to be contained in the insulating resin. In other words, the filler-reduction NCF 40E in the third modification may include an NCF in which the filler is not contained in the insulating resin.

Thus, the laminated chip, the laminated-chip-mounted substrate and the manufacturing method of the laminated chip according to the present application have been described with the embodiments. The present application is not limited to them. Then, it is evident to the person skilled in the art that various modifications, improvements, combinations and others are possible for the above embodiments.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A laminated chip comprising:
semiconductor chips that are laminated; and
multiple types of adhesive insulating resin films that include mutually different characteristics and that are filled between the semiconductor chips,
wherein the multiple types of the adhesive insulating resin films are arranged in a chip plane direction, depending on a demand characteristic for each region in a chip plane.

2. The laminated chip according to claim 1,
wherein one of the adjacent adhesive insulting resin films in the chip plane is pasted on a terminal formation surface of one of two semiconductor chips that are laminated, and the other of the adjacent adhesive insulating resin films is pasted on a terminal formation surface of the other of the two semiconductor chips that are laminated.

3. The laminated chip according to claim 1, further comprising an alignment mark formed on a first region in a terminal formation surface of one of the semiconductor chips,
wherein the adhesive insulating resin film pasted on the first region is lower in filler content than the adhesive insulating resin film pasted on a second region in a terminal formation surface of one of the semiconductor chips.

4. A laminated-chip-mounted substrate comprising:
a substrate;
a laminated chip that includes semiconductor chips that are laminated, the laminated chip being mounted on the substrate; and
multiple types of adhesive insulating resin films that include mutually different characteristics and that are filled between the semiconductor chips,
wherein the multiple types of the adhesive insulting resin film are arranged in a chip plane direction, depending on a demand characteristic for each region in a chip plane.

5. A manufacturing method of a laminated chip that is mounted on a substrate, the manufacturing method of the laminated chip comprising:
filling multiple types of adhesive insulating resin films that include mutually different characteristics between semiconductor chips; and
laminating the semiconductor chips to each other,
wherein, in the filling, the multiple types of the adhesive insulting resin films are arranged in a chip plane direction, depending on a demand characteristic for each region in a chip plane.
